(19) United States
(12) Patent Application Publication
(10) Pub. No.: US 2026/0010067 A1
(43) Pub. Date: Jan. 8, 2026

(54) PELLICLE FOR LITHOGRAPHY MASK AND METHOD OF MANUFACTURING THE SAME

(71) Applicant: Taiwan Semiconductor Manufacturing Company, Ltd., Hsinchu (TW)

(72) Inventors: Pei-Hsun Tsai, Hsinchu County (TW); Yun-Yue Lin, Hsinchu City (TW)

(21) Appl. No.: 18/934,597

(22) Filed: Nov. 1, 2024

Related U.S. Application Data
(60) Provisional application No. 63/668,079, filed on Jul. 5, 2024.

(51) Int. Cl. G03F 1/64

(52) U.S. Cl. CPC G03F 1/64

(57) ABSTRACT

A method of manufacturing an EUV pellicle, includes steps of depositing a first insulating layer on a substrate; partially removing the substrate to form an opening exposing the first insulating layer; partially removing the first insulating layer while leaving a supporting portion in contact with the substrate; forming a core layer on the supporting portion of the insulating layer, wherein the core layer comprises sp² and sp³ carbon atoms; and forming a hydrogen-barrier layer on the core layer.

### CROSS-REFERENCE TO RELATED APPLICATIONS

This application claims the benefit of U.S. Provisional Application No. 63/668,079, filed Jul. 5, 2024, the entire disclosure of which is incorporated by reference herein.

### BACKGROUND

A pellicle is a thin, transparent film stretched over a frame that is glued over one side of a reticle to protect a pattern on the reticle from damage, dust and/or moisture. In EUV lithography, a pellicle having a high transparency in EUV wavelengths, a high mechanical strength, a low thermal expansion, and resistance to hydrogen radicals is generally required.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic diagram of an exposure tool, in accordance with some embodiments of the present disclosure.

FIG. 2 is a schematic cross-sectional view of a reticle, a pellicle, and a frame for supporting the pellicle on the reticle, in accordance with some embodiments of the present disclosure.

FIG. 3 is a schematic bottom view of a pellicle and a frame, in accordance with some embodiments of the present disclosure.

FIG. 4 is a graph illustrating Raman spectra of a core layer in a pellicle membrane, in accordance with some embodiments of the present disclosure.

FIG. 5 is a graph illustrating work functions of various materials used in the core layer, in accordance with some embodiments of the present disclosure.

FIG. 6 is a graph illustrating a variation between each transition metal nitride material that is exposed to hydrogen radical and that is not exposed to the hydrogen radical, in accordance with some embodiments of the present disclosure.

FIG. 7 is a schematic cross-sectional view of a pellicle, in accordance with some embodiments of the present disclosure.

FIG. 8 is a schematic cross-sectional view of a pellicle, in accordance with some embodiments of the present disclosure.

FIG. 9 is a schematic cross-sectional view of a pellicle, in accordance with some embodiments of the present disclosure.

FIG. 10 is a flowchart showing a method of manufacturing a pellicle, in accordance with some embodiments of the present disclosure.

FIGS. 11 to 16 are cross-sectional views of intermediate stages of the method of manufacturing a pellicle, in accordance with some embodiments of the present disclosure.

FIG. 17 is a schematic diagram of vertical furnace for formation of nanotubes, in accordance with some embodiments of the present disclosure.

FIG. 18 is a flowchart showing a method of manufacturing a pellicle, in accordance with some embodiments of the present disclosure.

FIGS. 19 and 20 are cross-sectional views of intermediate stages of the method of manufacturing a pellicle, in accordance with some embodiments of the present disclosure.

FIG. 21 is a flowchart showing a method of manufacturing a pellicle, in accordance with some embodiments of the present disclosure.

FIGS. 22 and 23 are cross-sectional views of intermediate stages of the method of manufacturing a pellicle, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

The present disclosure is directed to a pellicle and a method for manufacturing the same. The pellicle in the present disclosure is used to protect a pattern of a reticle from particle contamination. The pellicle may include a pellicle membrane that includes a core layer formed from sp² and sp³ carbon atoms for providing a better mechanical and thermal performance compared to existing materials used for fabrication of pellicle membranes. The pellicle membrane further includes a barrier layer at least partially covering the core layer for protecting the core layer from hydrogen radicals/ions generated by extreme ultraviolet (EUV) or deep ultraviolet (DUV) radiation inside a lithography tool. Hence, the pattern of the reticle is not contaminated and the service life of the pellicle membrane may be extended. The barrier layer may include, for example, transition metal oxynitride or silicon carbide (SiC), wherein the transition metal may be selected from one of Group IV and Group V in Period IV in the periodic table.

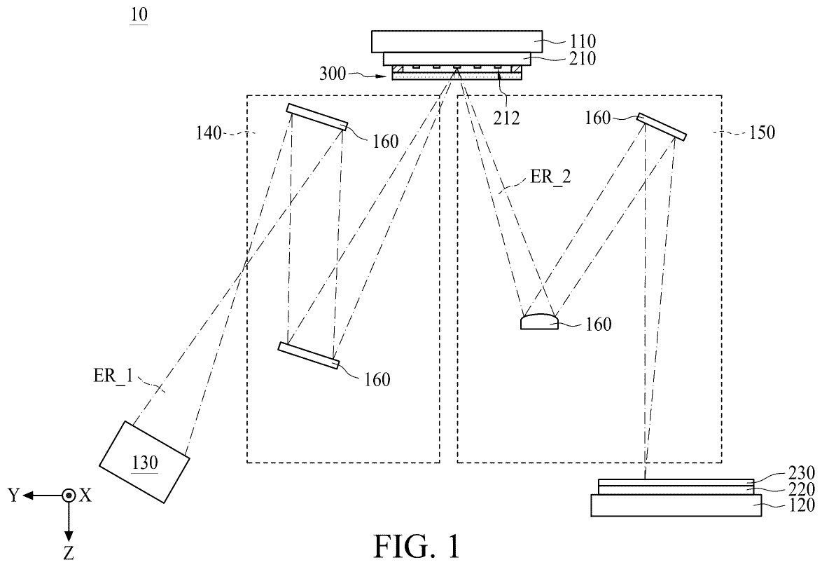

FIG. 1 is a schematic diagram of an exposure tool 10, in accordance with some embodiments of the present disclosure. Referring to FIG. 1, the exposure tool 10 can be used, for example, in the manufacture of integrated circuits. The exposure tool 10 may include a reticle stage 110, a substrate stage 120, a radiation source 130, an illumination optical module 140, and a projection optical module 150. In some embodiments, the reticle stage 110 secures a reticle 210 and provides accurate positioning and movement of the reticle 210 during exposure operations. The substrate stage 120 supports a substrate 220 and is capable of moving the substrate 220 with respect to the reticle 210. In some embodiments, a photoresist layer 230 is formed on the substrate 220. The photoresist layer 230 includes a radiation-sensitive material.

The radiation source 130 is configured to generate an electromagnetic radiation ER_1. The radiation source 130 may be any suitable optical source, such as a DUV source or an EUV source. The DUV source may generate DUV radiation with a wavelength centered at about 248 nm or about 193 nm. The EUV source may generate EUV radiation with a wavelength centered at about 13.5 nm. In embodiments where the exposure tool 10 includes the DUV source or the EUV source, the illumination optical module 140 and the projection optical module 150 include various reflective optical components, such as flat mirrors and/or multiple mirrors including reflective surfaces with convex or concave spherical shapes or aspheric shapes.

The illumination optical module 140 may be used to direct the electromagnetic radiation ER_1 generated by the radiation source 130 to the reticle 210. The reticle 210 is irradiated by the electromagnetic radiation ER_1, wherein a pattern 212 of the reticle 210 reflects and patterns the electromagnetic radiation ER_1 to form an electromagnetic radiation ER_2, carrying an image of the pattern 212 on the reticle 210. The projection optical module 150 may direct the electromagnetic radiation ER_2 onto the photoresist layer 230. The electromagnetic radiation ER_2 may cause a chemical transformation in the selected areas of the photoresist layer 230. In a subsequent development step, the selected areas or non-selected areas can be removed from the substrate 220. In such manner, the pattern 212 of the reticle 210 may be transferred to the photoresist layer 230 and thus a patterned photoresist layer is formed. The substrate 220 may then be further processed (e.g., materials may be removed, deposited, doped, etc.) through the patterned photoresist layer, thereby forming a patterned layer (corresponding to the pattern of the reticle 210) in or on the substrate 220.

In an embodiment that employs an EUV source as the radiation source 130, the EUV radiation is generated, for example, by illumination of a tin (Sn) droplet with a laser to form a tin plasma. In addition to generating the EUV radiation, the EUV source further generates undesirable by-products that may damage or reduce the operational efficiency of the illumination optical module 140 and the projection optical module 150. The by-products may include high-energy ions and scattered debris from the plasma formation, e.g., atoms and/or clumps/microdroplets of tin. The by-products may be deposited on the reflective optical components 160 (i.e., mirrors) of the illumination optical module 140 and the projection optical module 150. As such, the reflectivity of the mirrors with respect to the EUV radiation is degraded.

A mitigation technique for reducing or removing the by-products deposited onto the mirrors involves use of hydrogen radicals/ions. For example, a hydrogen-containing gas (e.g., H₂) is introduced into a chamber for receiving the exposure tool 10. During the exposure operation, the excitation of molecular hydrogen by the EUV radiation forms hydrogen radicals (H*) or hydrogen ions (H⁺). Some of the hydrogen radicals/ions in the exposure tool 10 react with the by-products to form volatile hydrides, such as tin hydrides, in the gaseous phase (at standard temperature and standard pressure in the exposure tool 10). The volatile hydrides may be at least partially removed by an exhaust or a pump. Thus, the mirrors are cleaned from tin contamination.

The reticle 210 may be used to reproducibly imprint hundreds or thousands of substrates 220 given a good condition of the reticle 210. Although efforts may be made to maintain a clean environment inside the exposure tool 10, particles may still be present inside the exposure tool 10. Particles falling on the reticle 210 may disadvantageously affect the pattern 212 that is carried by the electromagnetic radiation ER_2 and transferred to the substrate 220, and may cause yield issues and quality concerns. In order to protect the reticle 210 from particle contamination, the pattern 212 of the reticle 210 is protected by a pellicle 300. The pellicle 300 advantageously provides a barrier between the pattern 212 of the reticle 210 and the environment in the exposure tool 10 in order to prevent the particles from being disposed on the pattern 212 of the reticle 210.

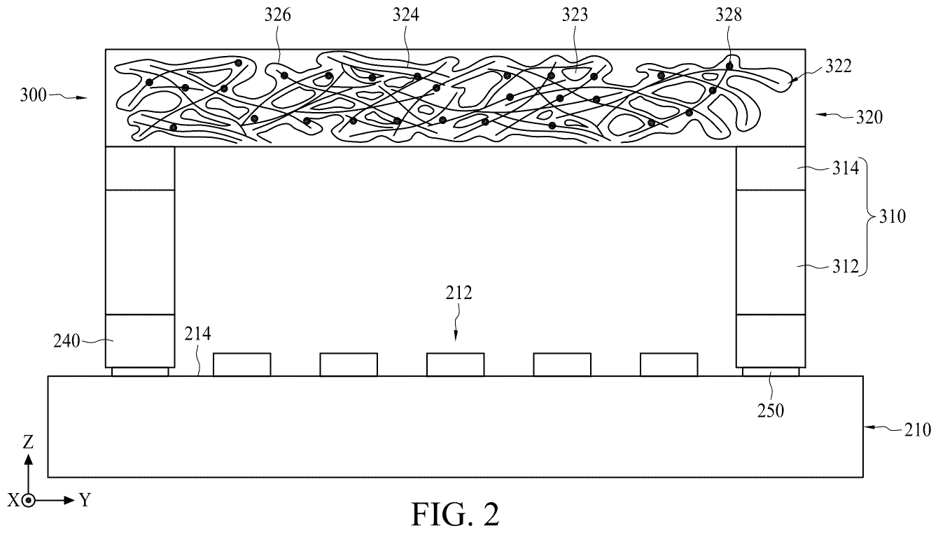

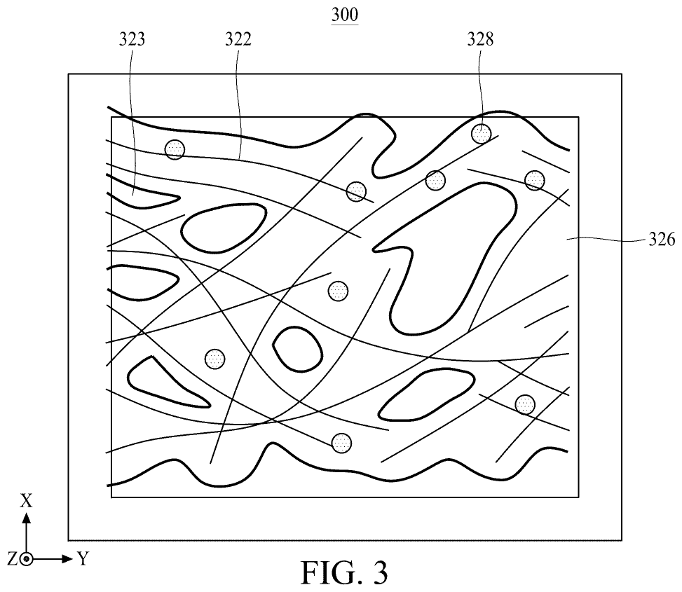

FIG. 2 is a schematic cross-sectional view of the reticle 210, the pellicle 300, and a frame 240 for supporting the pellicle 300 on the reticle 210, in accordance with some embodiments of the present disclosure. FIG. 3 is a schematic bottom view of the pellicle 300 and the frame 240, in accordance with some embodiments of the present disclosure. Referring to FIGS. 2 and 3, the reticle 210 includes a main surface 214 on which the pattern 212 is formed. In some embodiments, the frame 240 is attached to the main surface 214 of the reticle 210 and surrounds the pattern 212 on the reticle 210. The pellicle 300 may be positioned on the frame 240 and may include a pellicle membrane 320 extending over the pattern 212 of the reticle 210 to protect the pattern 212 from contaminant particles. Hence, any contamination which would otherwise be deposited on the pattern 212 of the reticle 210 is blocked by the pellicle membrane 320.

The frame 240 may have a ring shape from a bottom-view perspective. For example, the frame 240 may have a continuous rectangular ring shape and may encircle the pattern 212 on the reticle 210. Alternatively, the frame 240 may be designed with another other suitable ring shape such as a circle, a square or a polygon depending on an arrangement of the pattern 212 on the reticle 210. The frame 240 may be any material that has a high mechanical strength, a low tendency to attract dust, and a low weight. Hard plastics and materials such as aluminum or aluminum alloy may be suitable materials for the frame 240. The frame 240 may also be made of a material having a low coefficient of expansion. For example, the frame 240 includes titanium, quartz, silicon, or other suitable materials with low coefficient of expansion. The frame 240 is secured to the reticle 210, for example, through an adhesive layer 250 or any other suitable securing mechanism. The adhesive layer 250 may be tolerant of the electromagnetic the electromagnetic radiation ER_1 and ER_2 provided by the radiation source 130 shown in FIG. 1.

Referring back to FIG. 2, the pellicle 300 includes a pellicle border 310 and the pellicle membrane 320 is held in place by the pellicle border 310. In some embodiments, the pellicle border 310 is positioned on the frame 240 and supports the pellicle membrane 320 around a peripheral portion of the pellicle membrane 320. The pellicle border 310 may be designed in various dimensions, shapes, and configurations. In some embodiments, the pellicle border 310 has a rectangular ring shape similar to that of the underlying frame 240. The pellicle border 310 may at least partially overlap the frame 240. In an embodiment, the frame 240 and the pellicle border 310 have a uniform width, and the frame 240 is fully overlapped by the overlying pellicle border 310 to increase a coupling area and thus a coupling strength between the frame 240 and the pellicle border 310.

The pellicle border 310 is configured to support the pellicle membrane 320 and may include a single layer or multiple layers of material. As shown in FIG. 2, the pellicle border 310 includes a base layer 312 and a functional layer 314, wherein the base layer 312 is disposed between the frame 240 and the functional layer 314. The base layer 312 may include a material with good mechanical strength. The base layer 312 may include elementary semiconductor materials or compound semiconductor materials. In some embodiments, the base layer 312 includes elementary semiconductor materials such as silicon or germanium or compound semiconductor materials such as silicon carbide, gallium arsenide, indium arsenide, or indium phosphide.

The functional layer 314 serves to support the pellicle membrane 320. In some embodiments, the functional layer 314 is attached around the peripheral portion of the pellicle membrane 320, and thus the pellicle membrane 320 is stretched over the functional layer 314. In some embodiments, the pellicle membrane 320 may be, for example, attached to the functional layer 314 by van der Waals force. Alternatively, the pellicle membrane 320 may be glued to the functional layer 314 or attached to the functional layer 314 by another securing manner. The functional layer 314 includes dielectric material, such as oxide. The functional layer 314 may include silicon oxide (SiO) or silicon dioxide (SiO₂). The base layer 312 and the functional layer 314 of the pellicle border 310 and the frame 240 are utilized to position the pellicle membrane 320 at a sufficient defocus distance from the pattern 212 such that any particle on the pellicle membrane 320 will be out of focus during the exposure operation, and therefore will not be projected onto the substrate 220.

During the exposure operations, the electromagnetic radiation ER_2 may not reach deep portions of the photoresist layer 230 (i.e., the portions close to the substrate 220) sufficiently when a pellicle membrane has a low transmittance and/or high reflectance to the electromagnetic radiation ER_1 and ER_2, and thus one or more defective exposed regions tend to occur readily at a bottom of the photoresist layer 230. As a result, the pellicle membrane 320 is required to transmit the electromagnetic radiation ER_1 and ER_2 at a high transmittance. In some embodiments, the pellicle membrane 320 has a transmittance of about 92% or more in a wavelength range below about 250 nm. For example, the pellicle membrane 320 may have a transmittance between about 92% and about 94% with respect to the electromagnetic radiation having a wavelength of 13.5 nm. In some embodiments, the pellicle membrane 320 exhibits a reflectance less than about 20% in a wavelength range below about 250 nm. For example the pellicle membrane 320 may have a reflectance equal to or less than 0.05% with respect to the electromagnetic radiation in the EUV wavelength range. In another example, the pellicle membrane 320 has a reflectance less than about 0.01% with respect to the electromagnetic radiation having a wavelength of about 13.5 nm.

The pellicle membrane 320 is further required to have a high refractive index (approaching to 1) and a low extinction coefficient (substantially zero). The refractive index (n) may determine how much the path of electromagnetic radiation is bent, or refracted, when entering the pellicle membrane 320. The extinction coefficient (k) may refer to an amount of electromagnetic radiation absorbed by the pellicle membrane 320. Herein, the refractive index and the extinction coefficient are defined relative to EUV radiation (such as 13.5 nm) used in the exposure tool 10 shown in FIG. 1. In some embodiments, the pellicle membrane 320 has a refractive index between about 0.85 and about 1. In some embodiments, the pellicle membrane 320 has an extinction coefficient between about 0 and about 0.02.

The pellicle membrane 320 may include a core layer 322, an insulating layer 326, and a hydrogen-barrier layer 328. The core layer 322 is a carbon-based layer that has an amorphous structure in which sp³ bonds and sp² bonds are present in a mixed arrangement. In some embodiments, a ratio of sp² bonds to sp³ bonds, i.e., sp²/sp³, is between about 0.01 and about 100. A hardness and a residual stress may be controlled by varying the sp²/sp³ ratio. With increasing sp³ content, the core layer 322 becomes harder, but may also develop more residual compressive stress. Increasing sp² content reduces the hardness and the compressive strength, but may increase the ductility of the core layer 322.

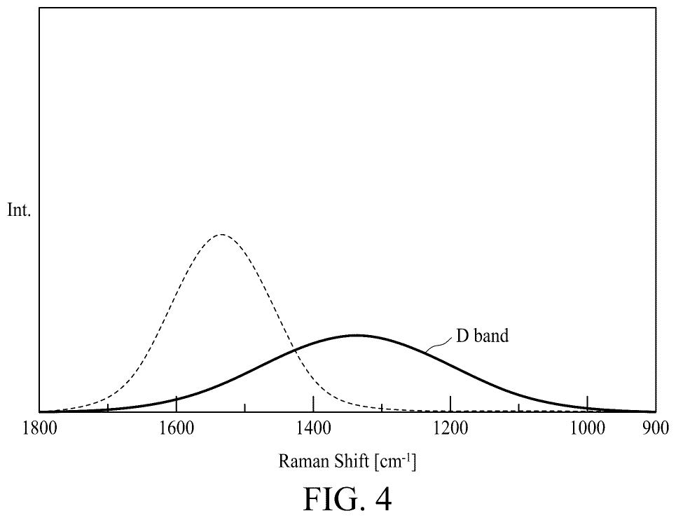

Referring to FIG. 4, when the core layer 322 is analyzed by Raman spectroscopy, peaks ordinarily occur in the vicinity of 1332 cm⁻¹ and in the vicinity of 1580 cm⁻¹. The spectrum in the vicinity of 1332 cm⁻¹ is called a D-band, and is a spectrum observed commonly in an sp³ hybrid orbital. The spectrum in the vicinity of 1590 cm⁻¹ is called a G-band, and is a spectrum observed commonly in an sp² hybrid orbital.

Referring back to FIGS. 2 and 3, the core layer 322 may include a plurality of nanotubes 324 that are randomly arranged to form a network structure. Each of the nanotubes 324 crosses one or more other nanotubes 324 to form a porous and intertwined structure. For example, the core layer 322 includes intertwined carbon nanotubes with interstitial spaces 323 therebetween. As such, the core layer 322 may be a porous core layer. The pellicle membrane 320 including the carbon nanotubes 324 is a promising option with high EUV transmission, low reflectivity, and good mechanical stability.

In some embodiments, the carbon nanotubes 324 are conformably coated with the insulating layer 326. For example, the carbon nanotubes 324 conformal to a circumference of each of the carbon nanotubes 324. The insulating layer 326 may encircle and be in contact with the carbon nanotubes 324. The carbon nanotubes 324 may be wrapped completely around by the insulating layer 326. In an example, the insulating layer 326 includes an inorganic material such as silicon oxynitride (SiON). When the insulating layer 326 is laminated on outer surfaces of the nanotubes 324, oxidation of the core layer 322 is suppressed during EUV irradiation or during storage of the pellicle 300.

In some embodiments, the hydrogen-barrier layer 328 at least partially covers the insulating layer 326. The hydrogen-barrier layer 328 on the insulating layer 326 may have a coverage in a range of about 10% to about 100% on the insulating layer 326. The hydrogen-barrier layer 328 helps to protect the core layer 322 from hydrogen radicals/ions that are used to reduce or remove the by-products deposited onto the mirrors of the illumination optical module 140 and the projection optical module 150. As such, the service life of the core layer 322 and thus the pellicle membrane 320 can be extended. The carbon-based core layer 322 may be protect by the hydrogen-barrier layer from damaged by the hydrogen radicals/ions.

In some embodiments, the hydrogen-barrier layer 328 includes a metal oxynitride. The hydrogen-barrier layer 328 may include an oxynitride of a transition metal selected from one of Group IV and Group V in the periodic table. For example, the hydrogen-barrier layer 328 is made of or includes a transition metal oxynitride of a metallic element such as titanium (Ti), vanadium (V), zirconium (Zr), hafnium (Hf), niobium (Nb), or tantalum (Ta). The hydrogen-barrier layers 328 may include oxygen, nitrogen, and the transition metal.

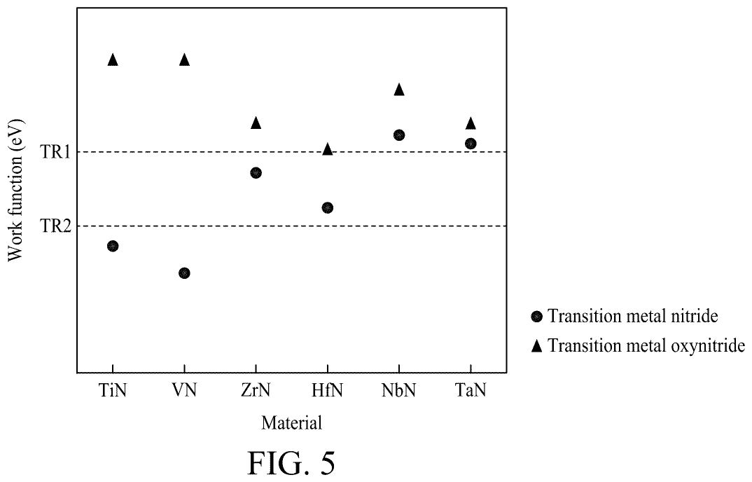

FIG. 5 is a graph illustrating work functions of various materials used in the core layer, in accordance with some embodiments of the present disclosure. The various materials shown in FIG. 5 includes transition metal nitrides. The transition metal nitrides includes titanium nitride (TiN), vanadium nitride (VN), zirconium nitride (ZrN), hafnium nitride (HfN), niobium nitride (NbN), and tantalum nitride (TaN). The transition metal nitrides are in a metastable state and tend to combine with oxygen to form transition metal oxynitrides on a surface in ambient conditions. As can be seen in FIG. 5, for the transition metal nitrides including the metallic element selected from one of Group IV and Group V in the periodic table, oxidation results in an increase of the work function.

In an embodiment, the transition metals having a low work function is more active, and thus more easily react with hydrogen radicals (as compared to the nitrogen or oxygen) and form a non-volatile by-product. Therefore, the reaction consumption induced by hydrogen radicals may be limited to near the surface of the material. On the other hand, the transition metals having a high work function is more inactive and do not easily react with the hydrogen, and thus the hydrogen radicals may more easily react with oxygen or nitrogen atoms near the surface of material to form water (H₂O) or ammonia (NH₃), which is a volatile by-product. Therefore, the reaction consumption induced by the hydrogen radicals may be deep into the hydrogen-barrier layer 328 without a stop at the surface, thereby corroding the entire hydrogen-barrier layer 328. Herein, the low work function may refer to a work function equal to or less than a first threshold voltage TR1, and the high work function may refer to a work function greater than the first threshold voltage TR1. Therefore, in some embodiments, TiN, VN, ZrN, and HfN are chosen for the formation of the hydrogen-barrier layer 238. In an example, the first threshold voltage may be equal to about 4.6 eV.

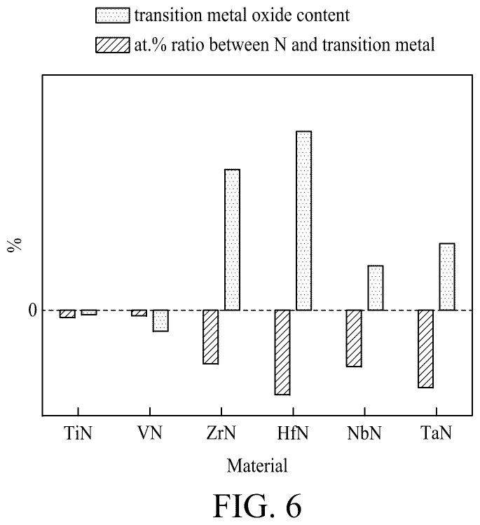

FIG. 6 is a graph illustrating a variation in oxygen and nitrogen content after transition metal nitrides are exposed to hydrogen radicals, in accordance with some embodiments of the present disclosure. As can be seen in FIG. 6, a positive value (greater than zero) indicates an increased amount of the variation, and a negative value (less than zero) indicates a decreased amount of the variation. Minor denitridation occurs in TiN and VN, wherein the transition metal oxide content is slightly reduced. In an embodiment, the hydrogen radical-induced reduction in TiN and VN is about 2 nm. Significant denitridation occurs in ZrN and HfN, along with an increase in the transition metal oxide content. Denitridation occurs in NbN and TaN as well, but the increase in the transition metal oxide content is less than that for ZrN and HfN and is greater than that for TiN and VN. Therefore, TiN and VN may be chosen for the formation of the hydrogen-barrier layer 238. As a result, the hydrogen-barrier layer 238 includes a transition metal in Group IV or Group V and in Period IV of the periodic table.

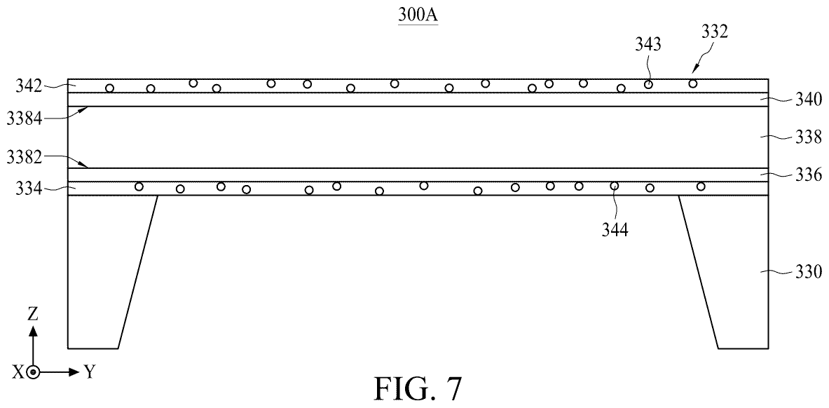

FIG. 7 is a schematic cross-sectional view of a pellicle 300A, in accordance with some embodiments of the present disclosure. Referring to FIG. 7, in some embodiments, the pellicle 300A includes a pellicle border 330 and a pellicle membrane 332 coupled to the pellicle border 330. The pellicle border 330 supports the pellicle membrane 332 around a peripheral portion of the pellicle membrane 332. The pellicle border 330 may have a tapered structure. For example, a width of the pellicle border 330 gradually decreases at positions of increasing distance from the pellicle membrane 332. The pellicle border 330 may be made of silicon wafer or another type of wafer.

In some embodiments, the pellicle membrane 332 includes a first hydrogen-barrier layer 334, a first cladding layer 336, a core layer 338, a second cladding layer 340, and a second hydrogen-barrier layer 342 sequentially disposed on the pellicle border 330. The core layer 338 may have a lower surface 3382 and an upper surface 3384 opposite to the lower surface 3382, wherein the lower surface 3382 is disposed closer to the pellicle border 330 than the upper surface 3384. The core layer 338 is a carbon-based layer that has an amorphous structure in which sp³ bonds and sp² bonds are present in a mixed arrangement. In some embodiments, the core layer 338 include a network of carbon nanotubes arranged in a mixed arrangement. For example, the core layer 338 is a porous layer that includes intertwined carbon nanotubes with interstitial spaces therebetween.

In some embodiments, at least one of the first hydrogen-barrier layer 334 and the second hydrogen-barrier layer 342 further includes an element 344 selected from a group consisting of silicon (Si), carbon (C), phosphorus (P), aluminum (Al), and niobium (Nb). The element 344 may help increase the mechanical strength of the first hydrogen-barrier layer 334. In some embodiments, an atomic percentage of the element 344 in the first hydrogen-barrier layer 334 is between about 0.01 at % and about 10 at %. For example, the atomic percentage of the element 344 in the first hydrogen-barrier layer 334 is in a range of about 0.01 at % to about 4 at %.

In some embodiments, the first cladding layer 336 is disposed on the lower surface 3382 of the core layer 338, and the second cladding layer 340 is disposed on the upper surface 3384 of the core layer 338. The first and second cladding layers 336 and 340 serve to prevent oxidation of the core layer 338 during exposure operations. The first and second cladding layers 336 and 340 may include a same material. An exemplary material of the first and second cladding layers 336 and 340 may include silicon nitride.

The first and second hydrogen-barrier layers 334 and 342 may help protect the core layer 338 from hydrogen radicals during exposure operations to extend the service life of the pellicle membrane 332. In some embodiments, the first hydrogen-barrier layer 334 at least partially covers the first cladding layer 336. In an example, the first hydrogen-barrier layer 334 may be disposed on a peripheral portion of the first cladding layer 336 and may contact the pellicle border 330, while a center portion of the first cladding layer 336 may be exposed through the pellicle border 330. The first hydrogen-barrier layer 334 may have a first coverage on the first cladding layer 336 between about 10% and about 100%. The first hydrogen-barrier layer 334 having the first coverage of about 100% may cover an entirety of the first cladding layer 336. The first hydrogen-barrier layer 334 having the first coverage of less than 100% may partially cover the first cladding layer 336. Hence, one or more portions of the first cladding layer 336 may be exposed through the first hydrogen-barrier layer 334.

The second hydrogen-barrier layer 342 is, for example, disposed on the second cladding layer 340. The second hydrogen-barrier layer 342 may have a second coverage on the second cladding layer 340 between about 10% and about 100%. The second coverage may be same as or different from the first coverage. In some embodiments, the first and second hydrogen-barrier layers 334 and 342 include a transition metal in Group IV or Group V and in Period IV of the periodic table. For example, the first and second hydrogen-barrier layers 334 and 342 include titanium or vanadium. The first and second hydrogen-barrier layers 334 may further include oxygen and nitrogen. In some embodiments, an atomic percentage of the transition metal in the first and second hydrogen-barrier layers 334 and 342 is between about 25 at % and about 50 at %, an atomic percentage of oxygen in the first and second hydrogen-barrier layers 334 and 342 is between about 25 at % and about 50 at %, and an atomic percentage of hydrogen in the first and second hydrogen-barrier layers 334 and 342 is between about 0% and about 25%.

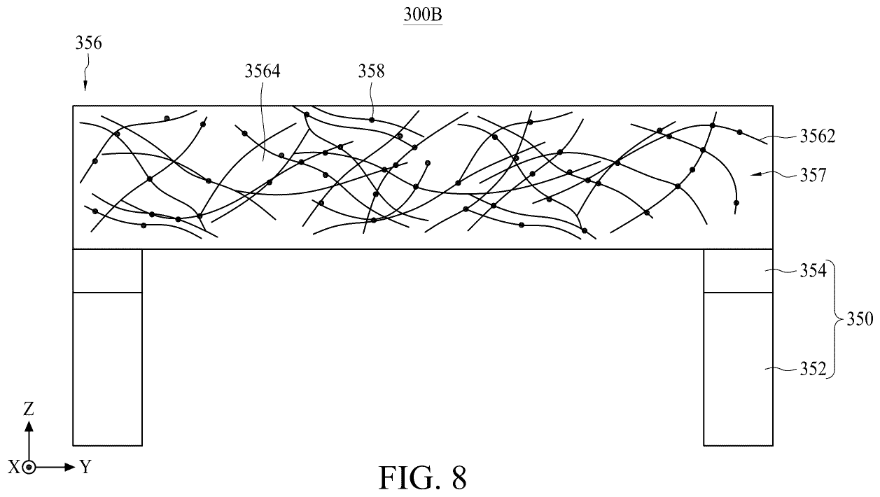

FIG. 8 is a schematic cross-sectional view of a pellicle 300B, in accordance with some embodiments of the present disclosure. Referring to FIG. 8, in some embodiments, the pellicle 300B includes a pellicle border 350 and a pellicle membrane 356 coupled to the pellicle border 350. The pellicle border 350 includes a base layer 352 and a functional layer 354 stacked on the base layer 352. The base layer 352 includes a material with good mechanical strength, such as a silicon wafer. In some embodiments, the functional layer 354 supports the pellicle membrane 356 around a peripheral portion of the pellicle membrane 356. The functional layer 354 may be made of dielectric material including oxide. For example, the functional layer 354 includes silicon oxide. The functional layer 354 may serve to help adhesion of the pellicle membrane 356 to the pellicle border 350.

In some embodiments, the pellicle membrane 356 includes a network of nanotubes 3562 and a hydrogen-barrier material 358 doped in the nanotubes 3562. The nanotubes 3562 are arranged randomly, to thereby form a porous membrane. The nanotubes 3562 may have an amorphous structure in which sp³ bonds and sp² bonds are present in a mixed arrangement. For example, the pellicle membrane 356 includes intertwined nanotubes 3562 with interstitial spaces 3564 therebetween. In some embodiments, the hydrogen-barrier material 358 includes transition metal oxynitride. The transition metal may be selected from one of Group IV and Group V and in Period IV of the periodic table. For example, the hydrogen-barrier material 358 includes titanium or vanadium.

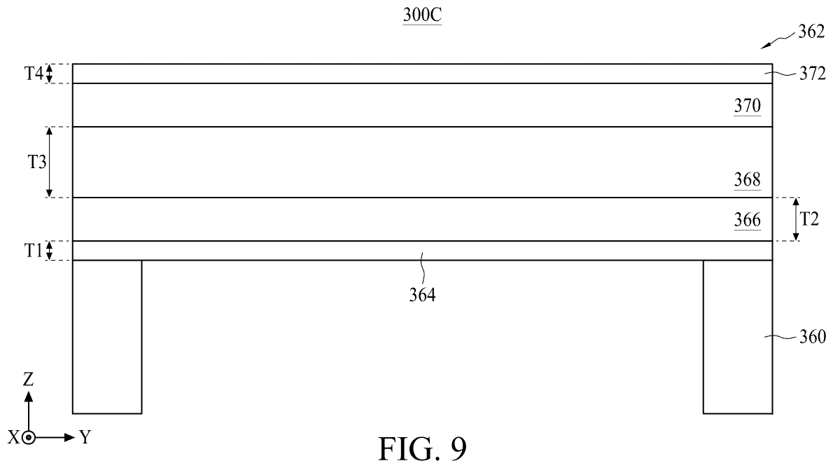

FIG. 9 is a schematic cross-sectional view of a pellicle 300C, in accordance with some embodiments of the present disclosure. Referring to FIG. 9, in some embodiments, the pellicle 300C includes a pellicle border 360 and a pellicle membrane 362 connected to the pellicle border 360. The pellicle border 360 supports the pellicle membrane 362 around a peripheral portion of the pellicle membrane 362. The pellicle border 360 may be formed from a portion of substrate, such as a substrate made of silicon wafer.

In some embodiments, the pellicle membrane 362 includes a first hydrogen-barrier layer 364, a first cladding layer 366, a core layer 368, a second cladding layer 370, and a second hydrogen-barrier layer 372 sequentially stacked over the pellicle border 360. The first hydrogen-barrier layer 364 may include a peripheral portion in contact with the pellicle border 360. In some embodiments, the first hydrogen-barrier layer 364 includes carbide, such as silicon carbide (SiC).

In some embodiments, the first hydrogen-barrier layer 364 at least partially covers the first cladding layer 366. In an example, the first hydrogen-barrier layer 364 may cover an entirety of a lower surface of the first cladding layer 366. In another example, one or more portions of the first cladding layer 366 are exposed through the first hydrogen-barrier layer 364. The exposed portion(s) of the first cladding layer 366 may be covered by or exposed through the pellicle border 360. The first cladding layer 366 is made of insulating material such as oxide. An exemplary material of the first cladding layer 366 may include silicon nitride. In some embodiments, the first hydrogen-barrier layer 364 has a thickness Tl less than a thickness T2 of the first cladding layer 366.

In some embodiments, the core layer 368 is a carbon-based layer. For example, the core layer 368 is a flat layer that is formed of diamond-like carbon (DLC). The diamond-like carbon has an intermediate crystalline structure between those of diamond and graphite. The core layer 368 has an amorphous structure in which sp³ bonds and sp² bonds are present in a mixed arrangement. In some embodiments, the core layer 368 may have a thickness T3 greater the thickness T2 of the first cladding layer 366.

In some embodiments, the second cladding layer 370 is disposed on the core layer 368. The second cladding layer 370 may include a material same as a material of the first cladding layer 366 (i.e., silicon dioxide). The second cladding layer 370 may include a thickness same as that of the first cladding layer 366. The first and second cladding layers 366 and 370 may serve to prevent oxidation of the core layer 368 during exposure operations.

The second hydrogen-barrier layer 372 at least partially covers the second cladding layer 370. In an embodiment, the second hydrogen-barrier layer 372 has a substantially uniform thickness T4, such that the second hydrogen-barrier layer 372 may have a coverage of about 100%. In another embodiment, the second hydrogen-barrier layer 372 has a non-uniform thickness T4, and one or more portions of the second cladding layer 370 may be exposed through the second hydrogen-barrier layer 372. In such embodiment, the second hydrogen-barrier layer 372 has a coverage of less than 100%. The coverage of the first hydrogen-barrier layer 364 on the first cladding layer 366 may be same as or different from the coverage of the second hydrogen-barrier layer 372 on the second cladding layer 370. In some embodiments, the second hydrogen-barrier layer 372 includes a material same as a material of the first hydrogen-barrier layer 364 (i.e., silicon carbide). The first and second hydrogen-barrier layers 364 and 372 may help protect the core layer 368 from hydrogen radicals during exposure operations to extend the service life of the pellicle membrane 362.

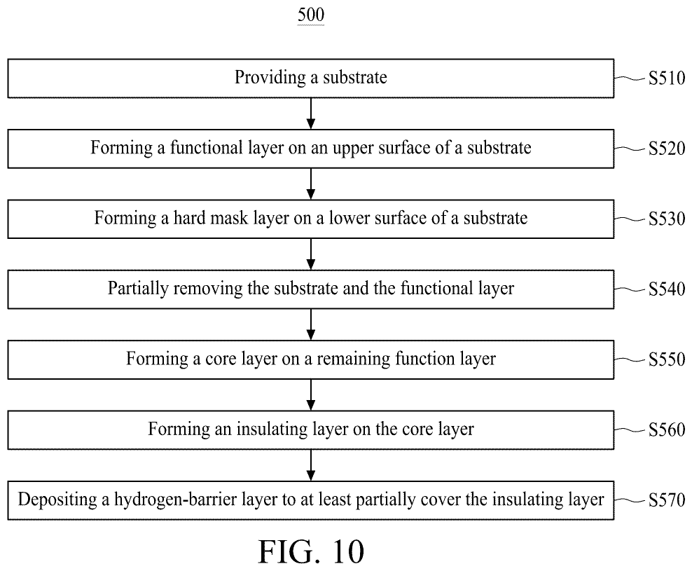

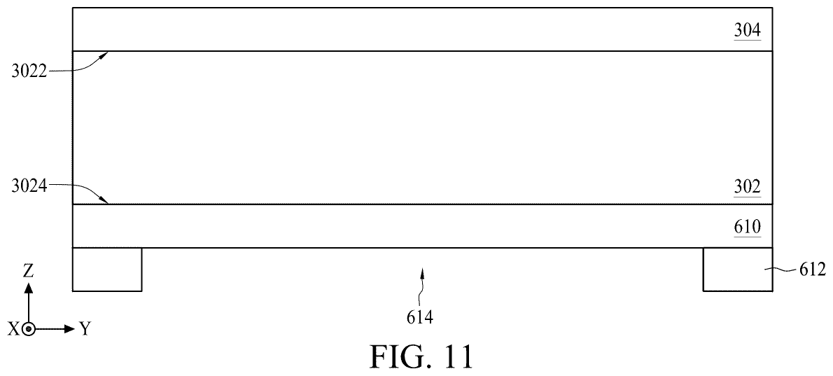

FIG. 10 is a flowchart showing a method 500 of manufacturing a pellicle 300, in accordance with some embodiments of the present disclosure. FIGS. 11 to 16 are cross-sectional views of intermediate stages of the method 500 of manufacturing the pellicle 300, in accordance with some embodiments of the present disclosure. In the following description, the manufacturing stages shown in FIGS. 11 to 16 are discussed with reference to the process steps shown in FIG. 10. It should be understood that additional steps can be provided before, during, and after the steps shown in FIG. 10, and some of the steps described below can be replaced or eliminated, for additional embodiments of the method 500. The order of the steps may be changed.

Referring to FIG. 11, a substrate 302 is provided in accordance with step S510 in FIG. 10. The substrate 302 may be a semiconductor substrate. In an embodiment, the substrate 302 is a bulk silicon substrate. In alternative embodiments, the substrate 302 includes an elementary semiconductor such as germanium, or includes a compound semiconductor, such as silicon germanium, silicon carbide, gallium arsenic, indium arsenide, and indium phosphide. The substrate 302 may have an upper surface 3022 and a lower surface 3024 opposite to the upper surface 3022.

Still referring to FIG. 11, a functional layer 304 is formed on the upper surface 3022 of the substrate 302 in accordance with step S520 in FIG. 10. In some embodiments, the functional layer 304 allows for the formation of a subsequent layer over the substrate 302. The functional layer 304 may include dielectric material, such as oxide. In some embodiments, the functional layer 304 is formed by performing a thermal oxidation operation; hence, the functional layer 304 includes a material provided by the substrate 302. In alternative embodiments, the functional layer 304 is disposed on an entirety of the upper surface 3022 of the substrate 302. The functional layer 304 may be formed to cover the upper surface 3022 of the substrate 302 by a chemical vapor deposition (CVD) operation, such as a plasma-enhanced CVD (PECVD) operation or a low-pressure CVD (LPCVD) operation. The functional layer 304 formed f from thermally-grown oxide may provide a high-quality semiconductor/dielectric interface of the final structure.

Subsequently, a sacrificial layer 610 is deposited on the lower surface 3024 of the substrate 302. The sacrificial layer 610 may include dielectric material, such as nitride. In an embodiment, the sacrificial layer 610 includes silicon nitride. The sacrificial layer 610 may be formed to cover an entirety of the lower surface 3024 of the substrate 302 by a PECVD operation or an LPCVD operation. Materials of the sacrificial layer 610 are not limited to examples described herein but may include a variety of suitable materials that withstand subsequent etching operations. By way of example, the sacrificial layer 610 may include silicon oxynitride, silicon carbonitride, the like, or combinations thereof.

After the sacrificial layer 610 is completely formed, a photoresist mask layer 612 is formed on the sacrificial layer 610. The photoresist mask layer 612 may be used to pattern the sacrificial layer 610. In some embodiments, the photoresist mask layer 612 includes an opening 614 to expose a region of the sacrificial layer 610. For example, the photoresist mask layer 612 is formed to expose a center portion of the sacrificial layer 610 and cover a peripheral portion of the sacrificial layer 610. The formation of the photoresist mask layer 612 may include forming of a blanket photoresist layer on the sacrificial layer 610, and patterning the blanket photoresist layer using a lithography operation. In some embodiments, the blanket photoresist layer is a radiation-sensitive layer. For example, the photoresist mask layer 612 may be sensitive to DUV or EUV radiation. The lithography operation for patterning the blanket photoresist layer includes DUV or EUV lithography operations. A shape of the opening 614 may be adjusted as required. In an embodiment, the opening 614 has a rectangular shape, from a plan view perspective.

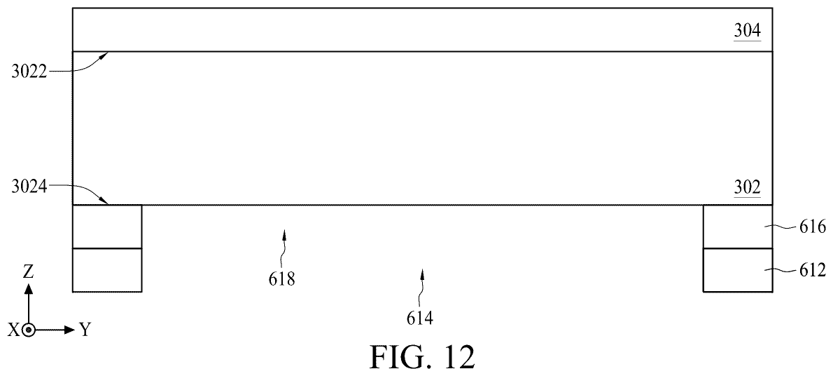

Referring to FIG. 12, the sacrificial layer 610 is patterned to form a hard mask layer 616 on the lower surface 3024 of the substrate 302 in accordance with step S530 in FIG. 10. In some embodiments, the hard mask layer 616 is formed using an etching operation. The hard mask layer 616 may be etched through the opening 614, so that a via-hole 618 is formed in the hard mask layer 616. The hard mask layer 616 is etched until a region of the substrate 302 is exposed. The etching operation may include a wet etch, a dry etch, a combination thereof, or the like. After the hard mask layer 616 is formed, the photoresist mask layer 612 is removed, for example, in an ashing and/or wet strip operation.

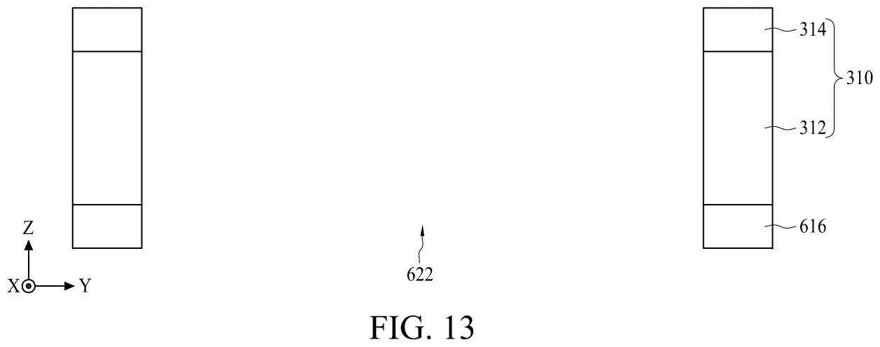

Referring to FIG. 13, at least one removal operation is performed to partially remove the substrate 302 and the functional layer 304 in accordance with step S540 in FIG. 10. Portions of the substrate 302 and the functional layer 304 not covered by the hard mask layer are removed by multiple etching steps using different etchants selected for particular materials of the substrate 302 and the functional layer 304. In some embodiments, the substrate 302 and the functional layer 304 are anisotropically etched by plasma-based etching operations, such as reactive ion etching (RIE) operations, or the like. The hard mask layer 616 is used to limit a high-energy plasma etch to a desired pattern for the via-hole 618.

After the etching of the substrate 302, a center portion of the substrate 302 is removed while keeping a peripheral portion of the substrate 302 intact. Hereinafter, the peripheral portion of substrate 302 is referred to as a remaining substrate 312. In addition, a portion of the functional layer 304 that is exposed by the remaining substrate 312 is removed while leaving a remaining functional layer 314 substantially intact. The remaining substrate 312 and the remaining functional layer 314 may form a pellicle border 310 having a ring shape from a bottom-view perspective.

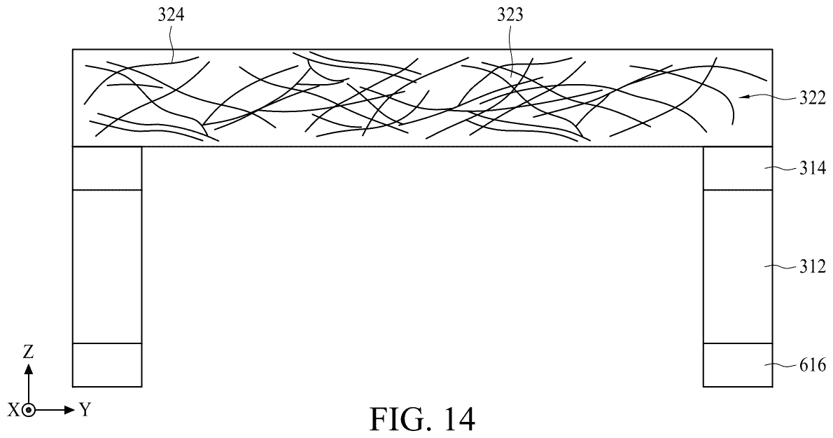

Referring to FIG. 14, a core layer 322 is formed on the remaining functional layer 314 in accordance with step S550 in FIG. 10. The core layer 322 may be a carbon-based layer that includes both sp² and sp³ hybridized carbons. In some embodiments, the core layer 322 includes a network of carbon nanotubes 324. The carbon nanotubes 324 are arranged in an irregular or random configuration, such that the carbon nanotubes 324 may cross one another to form interstitial spaces 323 therebetween.

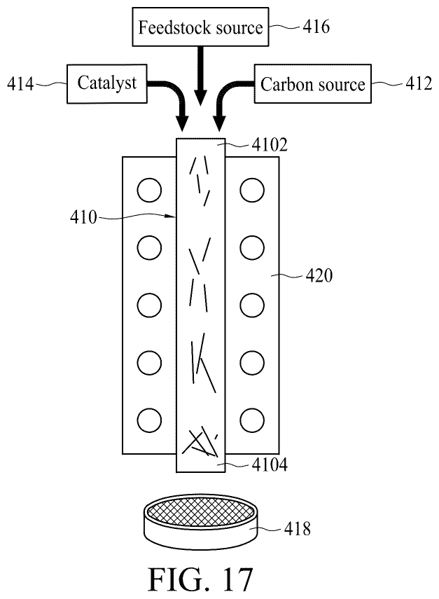

In some embodiments, the carbon nanotubes 324 are formed by a CVD operation. For example, the CVD operation for the formation of the carbon nanotubes 324 is performed using a vertical furnace as shown in FIG. 17. Referring to FIG. 17, the vertical furnace may be configured to continuously generate the carbon nanotubes 324 and includes a tubular chamber 410, a carbon source 412, a catalyst source 414, a feedstock source 416, a collector 418, and one or more heating members 420. The tubular chamber 410 defines a reaction zone for the formation of the carbon nanotubes 324. The tubular chamber 410 includes an upper portion 4102 and a lower portion 4104 that is opposite to the upper portion 4102. The carbon source 412 is used to supply a carbon precursor to the tubular chamber 410, and the catalyst source 414 is used to supply a catalyst to the tubular chamber 410. The feedstock source 416 may provide a flow of carrier gas (e.g., nitride gas) at a predetermined rate to the tubular chamber 410.

In some embodiments, the carbon precursor, the catalyst, and the carrier gas are introduced into the reaction zone from the upper portion 4102 of the tubular chamber 410. The heating members 420 may be disposed around the tubular chamber 410 and configured to heat the tubular chamber 410, and to thereby vaporize the carbon precursor. In some embodiments, the carbon nanotubes 324 are synthesized in the reaction zone, and aggregates of the carbon nanotubes 324 and the carrier gas descend to the lower portion 4104 of the tubular chamber 410. The aggregates of the carbon nanotubes 324 are wound up to form a network structure. The aggregates of the carbon nanotubes 324 may be collected at the lower portion 4104 of the tubular chamber 410, such as by the collector 418.

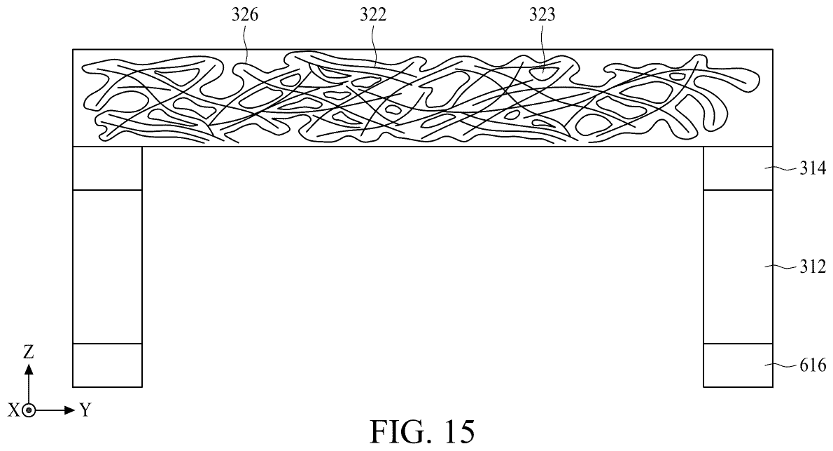

Referring to FIG. 15, an insulating layer 326 is deposited on the core layer 322 in accordance with step S560 in FIG. 10. In some embodiments, the carbon nanotubes 324 are coated with the insulating layer 326. The insulating layer 326 may include silicon nitride. The insulating layer 326 may be formed or deposited by CVD operation, a physical vapor deposition (PVD) operation, an atomic layer deposition (ALD) operation, or another applicable deposition operation.

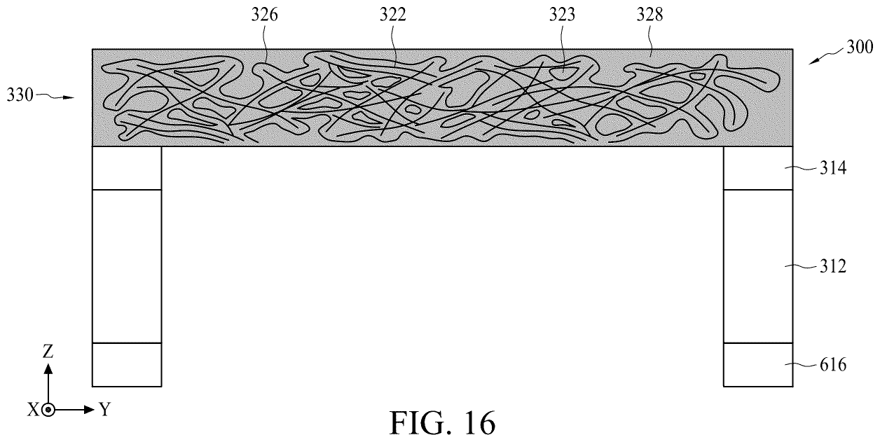

Referring to FIG. 16, a hydrogen-barrier layer 328 is deposited to at least partially cover the insulating layer 326 in accordance with step S570 in FIG. 10. The hydrogen-barrier layer 328 may include a material layer that is resistant to hydrogen radicals. The hydrogen-barrier layer 328 includes a transition metal selected from one of Group IV and Group V in Period IV of the periodic table. For example, the hydrogen-barrier layer 328 includes titanium or vanadium. The hydrogen-barrier layer 328 may have a coverage on the insulating layer 326 between about 10% and about 100%. The coverage of the hydrogen-barrier layer 328 on the insulating layer 326 may be determined according to a DUV or an EUV transmittance. A pellicle membrane that includes the insulating layer 326 that is completely covered by the hydrogen-barrier layer 328 may have a lower transmittance performance than a pellicle membrane that includes the insulating layer 326 that is only partially covered by the hydrogen-barrier layer 328. The hydrogen-barrier layer 328 may be formed or deposited by a CVD operation, a PVD operation, an ALD operation, or another applicable deposition operation. After the hydrogen-barrier layer 328 is completely formed, the hard mask layer 616 is removed by any suitable technique, such as wet etching. Consequently, the pellicle 300 is completely formed. As illustrated in FIG. 16, the pellicle 300 includes the insulating layer 326 is completely covered by the hydrogen-barrier layer 328, while the insulating layer 326 illustrated in FIGS. 2 and 3 are partially covered by the hydrogen-barrier layer 328.

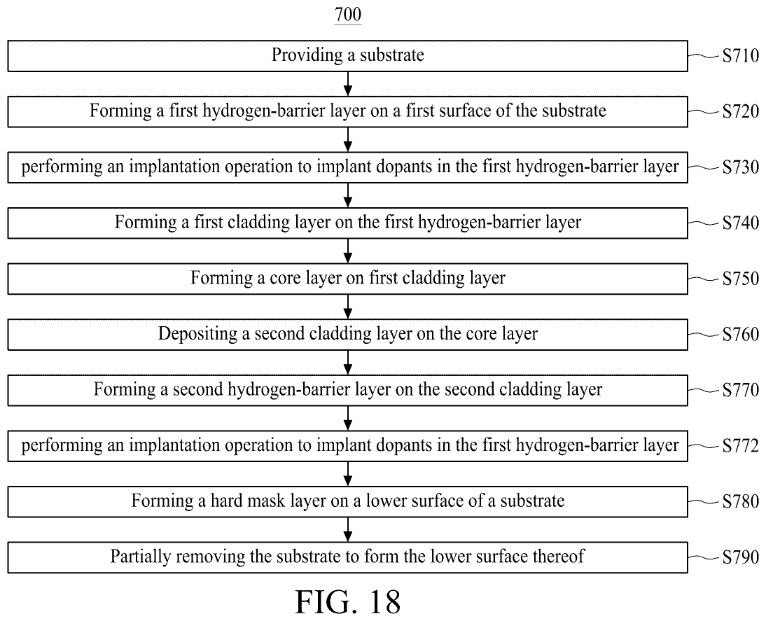

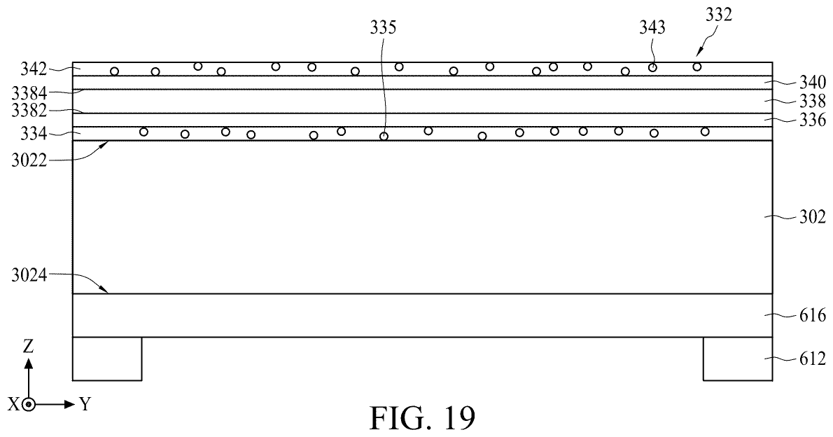

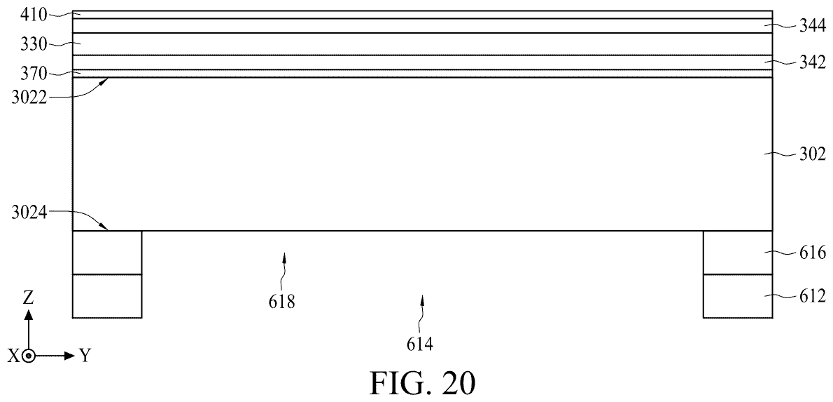

FIG. 18 is a flowchart showing a method 700 of manufacturing a pellicle 300A, in accordance with some embodiments of the present disclosure. FIGS. 19 and 20 are cross-sectional views of intermediate stages of the method 700 of manufacturing the pellicle 300A, in accordance with some embodiments of the present disclosure. In the following description, the manufacturing stages shown in FIGS. 19 and 20 are discussed with reference to the process steps shown in FIG. 18. It should be understood that additional steps can be provided before, during, and after the steps shown in FIG. 18, and some of the steps described below can be replaced or eliminated, for additional embodiments of the method 700. The order of the steps may be changed.

Referring to FIG. 19, a substrate 302 is provided in accordance with step S710 in FIG. 18. The substrate 302 includes an upper surface 3022 and a lower surface 3024 opposite to the upper surface 3022. The substrate 302 may be a part of a semiconductor wafer, for example, a silicon wafer. The substrate 302 may be composed of any semiconductor material, including but not limited to a silicon-containing semiconductor material, a germanium-containing semiconductor material, or any combination thereof.

Subsequently, a first hydrogen-barrier layer 334 is formed on the upper surface 3022 of the substrate 302 in accordance with step S720 in FIG. 18. The first hydrogen-barrier layer 334 may be deposited to at least partially cover the upper surface 3022 of the substrate 302. In an example, the first hydrogen-barrier layer 334 may have a uniform thickness to cover an entirety of the upper surface 3022 of the substrate 302. In another embodiment, the first hydrogen-barrier layer 334 on the upper surface 3022 of the substrate 302 may have a non-uniform thickness, and one or more regions of the upper surface 3022 of the substrate 302 may be exposed through the first hydrogen-barrier layer 334. The uniformity of the first hydrogen-barrier layer 334 may vary depending on a deposition duration. For example, a greater deposition duration may be required to sufficiently cover the upper surface 3022 of the substrate 302, which may lead to the first hydrogen-barrier layer 334 having a substantially uniform thickness. In some embodiments, the first hydrogen-barrier layer 334 includes oxygen, hydrogen, and a transition metal selected from one of Group IV and Group V in Period IV in the periodic table. The first hydrogen-barrier layer 334 is formed by CVD, PVD, ALD, and/or other suitable methods.

After the deposition of the first hydrogen-barrier layer 334, an implantation operation may be performed to implant dopants 335 in the first hydrogen-barrier layer 334 in accordance with step S730 in FIG. 18. The dopant 335 may be selected from a group consisting of silicon, carbon, boron, phosphorus, aluminum, and niobium. In some embodiments, an atomic percentage of the dopant 335 in the first hydrogen-barrier layer 334 is between about 0.01 at % and about 10 at %.

The method 700 continues with step S740, in which a first cladding layer 336 is deposited to cover at least a portion of the first hydrogen-barrier layer 334. The first cladding layer 336 may cover the first hydrogen-barrier layer 334 and one or more regions of the upper surface 3022 of the substrate 302 exposed through the first hydrogen-barrier layer 334. The first cladding layer 336 is made of dielectric material that includes oxide and nitride. In an example, the first cladding layer 336 includes silicon oxynitride. The first cladding layer 336 is formed by CVD, PVD, ALD, and/or other suitable methods.

Subsequently, a core layer 338 is formed on the first cladding layer 336 in accordance with step S750 in FIG. 18. The core layer 338 may include a plurality of nanotubes that cross one another to form a network. The core layer 338 may be formed by a CVD operation as described above.

The method 700 continues with step S760, in which a second cladding layer 340 is deposited on the core layer 338. In some embodiments, the second cladding layer 340 covers an entirety of a surface of the core layer 338. The second cladding layer 340 may include dielectric material, such as oxynitride. The first and second cladding layers 336 and 340 include a same material. The second cladding layer 340 is formed by CVD, PVD, ALD, and/or other suitable methods.

Subsequently, a second hydrogen-barrier layer 342 is formed on the second cladding layer 340 in accordance with step S770 in FIG. 18. The second hydrogen-barrier layer 342 may be deposited to at least partially cover a surface 3402 of the second cladding layer 340. The second hydrogen-barrier layer 342 may have a uniform or a non-uniform thickness. In an example, one or more regions of the second cladding layer 340 may be exposed through the second hydrogen-barrier layer 342 when the second hydrogen-barrier layer 342 has the non-uniform thickness. The first and second hydrogen-barrier layers 334 and 342 may be made of a same material. The second hydrogen-barrier layer 342 is formed by CVD, PVD, ALD, and/or other suitable methods.

After the second hydrogen-barrier layer 342 is formed, an implantation operation is performed to implant dopants 343 into the second hydrogen-barrier layer 342 in accordance with step S772 in FIG. 18. The dopant 343 in the second hydrogen-barrier layer 342 may be same as or different from the dopant 335 in the first hydrogen-barrier layer 334.

Subsequently, a sacrificial layer 610 is deposited on the lower surface 3024 of the substrate 302. The sacrificial layer 610 may include dielectric material, such as nitride. The sacrificial layer 610 may be formed to cover an entirety of the lower surface 3024 of the substrate 302 by a PECVD operation or an LPCVD operation. After the sacrificial layer 610 is completely formed, a photoresist mask layer 612 is formed on the sacrificial layer 610. The photoresist mask layer 612 may be used to pattern the sacrificial layer 610. In some embodiments, the photoresist mask layer 612 includes an opening 614 to expose a region of the sacrificial layer 610.

Referring to FIG. 20, the sacrificial layer 610 is patterned to form a hard mask layer 616 on the lower surface 3024 of the substrate 302 in accordance with step S780 in FIG. 18. In some embodiments, the hard mask layer 616 is formed using an etching operation. The hard mask layer 616 may be etched through the opening 614, so that a via-hole 618 is formed in the hard mask layer 616. The hard mask layer 616 is etched until a region of the substrate 302 is exposed. The etching operation may include a wet etch, a dry etch, a combination thereof, or the like. After the hard mask layer 616 is formed, the photoresist mask layer 612 is removed, for example, in an ashing and/or wet strip operation.

Subsequently, at least one removal operation is performed to partially remove the substrate 302 in accordance with step S790 in FIG. 18. Consequently, the pellicle 300A shown in FIG. 7 is completely formed. In some embodiments, a center portion of the substrate 302 not covered by the hard mask layer 616 is removed by an etching operation. After the etching operation, a portion of the first hydrogen-barrier layer 334 is exposed. The hard mask layer 616 is then removed by any suitable technique, such as wet etching.

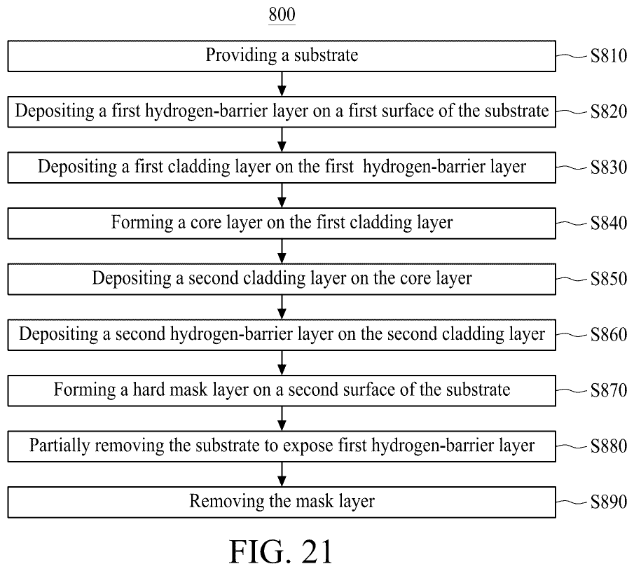

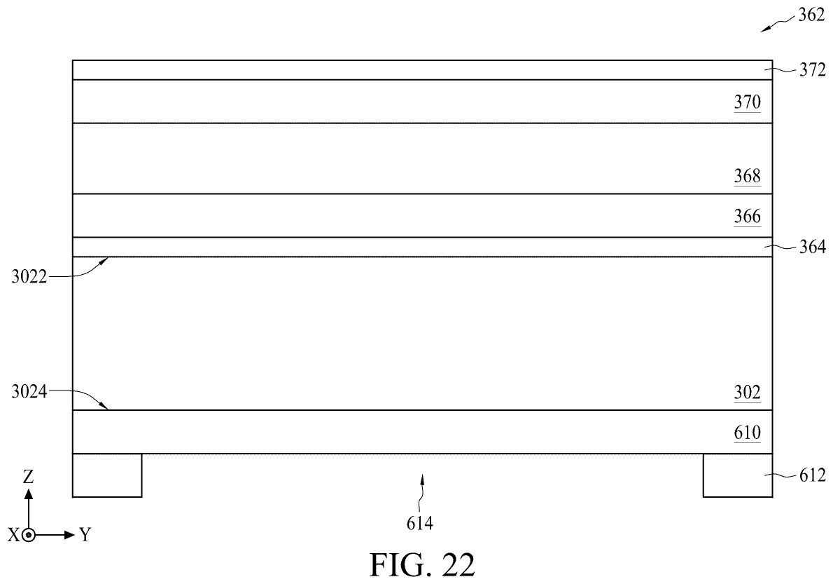

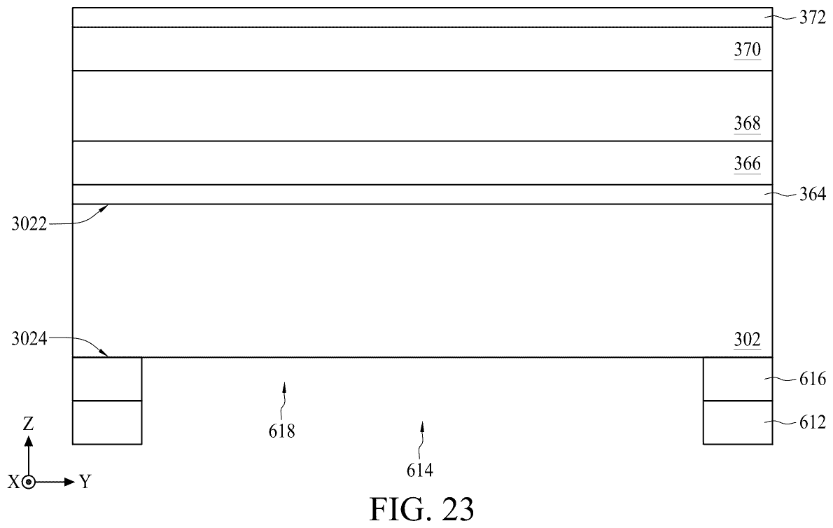

FIG. 21 is a flowchart showing a method 800 of manufacturing a pellicle 300B, in accordance with some embodiments of the present disclosure. FIGS. 22 and 23 are cross-sectional views of intermediate stages of the method 800 of manufacturing the pellicle 300B, in accordance with some embodiments of the present disclosure. In the following description, the manufacturing stages shown in FIGS. 22 and 23 are discussed with reference to the process steps shown in FIG. 21. It should be understood that additional steps can be provided before, during, and after the steps shown in FIG. 21, and some of the steps described below can be replaced or eliminated, for additional embodiments of the method 800. The order of the steps may be changed.

Referring to FIG. 22, a substrate 302 is provided in accordance with step S810 in FIG. 21. In some embodiments, the substrate 302 is a semiconductor substrate. For example, the substrate 302 may be a silicon substrate. The substrate 302 includes an upper surface 3022 and a lower surface 3024 opposite to the upper surface 3022.

Still referring to FIG. 22, a first hydrogen-barrier layer 364 is deposited on at least a portion of the upper surface 3022 of the substrate 302 in accordance with step S820 in FIG. 21. In some embodiments, the first hydrogen-barrier layer 364 includes silicon carbide. The first hydrogen-barrier layer 364 may be formed by CVD, PVD, ALD, and/or other suitable methods.

Subsequently, a first cladding layer 366 is deposited on the first hydrogen-barrier layer 364 in accordance with step S830 in FIG. 21. In some embodiments, the first cladding layer 366 includes dielectric material, such as oxide. For example, the first cladding layer 366 may include silicon dioxide.

The method 800 continues with step S840, in which a core layer 368 is deposited on the first cladding layer 366. The core layer 368 may include sp² and sp³ carbon atoms. In some embodiments, the core layer 368 includes the carbon atoms bonded to each other by sp³ hybrid orbitals, as well as the carbon atoms bonded to each other by sp² hybrid orbitals. For example, the core layer 368 may include diamond-like carbon (DLC). The core layer 368 may be formed by CVD, PVD, or ALD.

After the core layer 368 is completely formed, a second cladding layer 370 is deposited on the core layer 368 in accordance with step S850 in FIG. 21. The second cladding layer 370 may have a material same as a material of the first cladding layer 366.

The method 800 then proceeds to step S860, in which a second hydrogen-barrier layer 372 is deposited on the second cladding layer 370. In some embodiments, the second hydrogen-barrier layer 372 includes dielectric material. For example, the second hydrogen-barrier layer 372 may have a material same as a material of the first hydrogen-barrier layer 364.

After the second hydrogen-barrier layer 372 is completely formed, a sacrificial layer 610 is deposited on the lower surface 3024 of the substrate 302. The sacrificial layer 610 may include dielectric material, such as nitride. In an embodiment, the sacrificial layer 610 includes silicon nitride. After the formation of the sacrificial layer 610, a photoresist mask layer 612 is formed on the sacrificial layer 610. The photoresist mask layer 612 is formed on the sacrificial layer 610 by a lithographic operation that includes steps of applying a photoresist layer, exposing the photoresist layer through a photomask, and developing the exposed photoresist layer to form an opening 614 that exposes a region of the sacrificial layer 610.

Referring to FIG. 23, the sacrificial layer 610 is patterned to form a hard mask layer 616 on the lower surface 3024 of the substrate 302 in accordance with step S870 in FIG. 21. In some embodiments, the hard mask layer 616 is formed using an etching operation. The hard mask layer 616 may be etched through the opening 614, so that a via-hole 618 is formed in the hard mask layer 616. The hard mask layer 616 is etched until a region of the substrate 302 is exposed. The etching operation may include a wet etch, a dry etch, a combination thereof, or the like. After the hard mask layer 616 is formed, the photoresist mask layer 612 is removed, for example, in an ashing and/or wet strip operation.

Subsequently, the substrate 302 is partially removed to expose a portion of the first hydrogen-barrier layer 364 in accordance with step S880 in FIG. 21. Consequently, the pellicle 300C shown in FIG. 9 is completely formed. The hard mask layer 616 is then removed using any suitable method in accordance with step S890 in FIG. 21.

In accordance with some embodiments of the present disclosure, a method of manufacturing a pellicle includes steps of depositing a first insulating layer on a substrate; partially removing the substrate to form an opening exposing the first insulating layer; partially removing a portion of the first insulating layer exposed through a remaining substrate to form a pellicle border; forming a core layer on the pellicle border, wherein the core layer comprises sp² and sp³ carbon atoms; and forming a hydrogen-barrier layer at least partially covering the core layer so that a pellicle membrane is formed on the pellicle border.

In accordance with some embodiments of the present disclosure, a method of manufacturing a pellicle includes steps of providing a substrate having a first surface and a second surface opposite to the first surface; forming a first hydrogen-barrier layer at least partially covering the first surface of the substrate; depositing a core layer on the first hydrogen-barrier layer, wherein the core layer comprises sp² bonds and sp³ bonds; forming a second hydrogen-barrier layer at least partially covering the core layer as to form a pellicle membrane; and partially removing the substrate to form a pellicle border coupled to the pellicle membrane.

In accordance with some embodiments of the present disclosure, a pellicle membrane includes a core layer and a hydrogen-barrier material; the core layer comprises a carbon nanostructure including a combination of sp² bonds and sp³ bonds; and the hydrogen-barrier material is distributed in the core layer, wherein the hydrogen-barrier material comprises a transition metal selected from one of Group IV or Group V of the periodic table.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a pellicle, comprising:
depositing a first insulating layer on a substrate;
partially removing the substrate to form an opening exposing the first insulating layer;
removing a portion of the first insulating layer exposed through a remaining portion of the substrate to form a pellicle border;
forming a core layer on the pellicle border, wherein the core layer comprises sp² bonds and sp³ bonds; and
forming a hydrogen-barrier layer at least partially covering the core layer.

2. The method according to claim 1, wherein a coverage of the hydrogen-barrier layer over the core layer is between about 10% and about 100%.

3. The method according to claim 2, further comprising:
depositing a second insulating layer on the core layer prior to the formation of the hydrogen-barrier layer.

4. The method according to claim 3, wherein the second insulating layer comprises a silicon-containing dielectric material.

5. The method according to claim 1, wherein the hydrogen-barrier layer comprises a transition metal selected from one of Group IV and Group V of the periodic table.

6. The method according to claim 5, wherein the transition metal is selected from Period IV of the periodic table.

7. The method according to claim 5, wherein the hydrogen-barrier layer further comprises oxygen and hydrogen.

8. The method according to claim 7, wherein an atomic percentage of oxygen in the hydrogen-barrier layer is substantially equal to an atomic percentage of the transition metal in the hydrogen-barrier layer, and an atomic percentage of hydrogen in the hydrogen-barrier layer is less than the atomic percentage of oxygen in the hydrogen-barrier layer.

9. The method according to claim 1, further comprising:
doping the hydrogen-barrier layer with a dopant selected from a group consisting of silicon, carbon, boron, phosphorus, aluminum, and niobium.

10. The method according to claim 1, wherein a bonding ratio of sp² carbon atoms to sp³ carbon atoms in the core layer is between about 0.01 and about 100.

11. The method according to claim 1, wherein the core layer comprises carbon nanotubes that cross each other to form a network.

12. A method of manufacturing a pellicle, comprising:
providing a substrate having a first surface and a second surface opposite to the first surface;
forming a first hydrogen-barrier layer at least partially covering the first surface of the substrate;
depositing a core layer on the first hydrogen-barrier layer, wherein the core layer comprises sp² bonds and sp³ bonds;
forming a second hydrogen-barrier layer at least partially covering the core layer to form a pellicle membrane; and
partially removing the substrate to form a pellicle border coupled to the pellicle membrane.

13. The method according to claim 12, wherein the core layer comprises diamond like carbon (DLC) and the first and second hydrogen-barrier layers comprise:
a cladding film in contact with the core layer; and
a passivation film disposed on the cladding film,
wherein the cladding film and the passivation film comprise silicon-containing dielectric materials.

14. The method according to claim 12, wherein the core layer comprises carbon nanotube (CNT) material, the method further comprising:
depositing a first insulating layer on the first hydrogen-barrier layer prior to the deposition of the core layer; and
depositing a second insulating layer on the core layer prior to the deposition of the second hydrogen-barrier layer,
wherein a coverage of the first and second hydrogen-barrier layers is between about 10% and about 100%.

15. The method according to claim 12, wherein the first and second hydrogen-barrier layers have an extinction coefficient less than about 0.02.

16. The method according to claim 12, wherein the first and second hydrogen-barrier layers comprise a transition metal in Group IV or Group V and in Period IV of the periodic table.

17. The method according to claim 12, wherein the partial removal of the substrate comprises:
removing a center portion of the substrate while keeping a peripheral portion of the substrate intact.

18. A pellicle membrane, comprising:
a core layer of carbon nanostructure comprising a combination of sp² bonds and sp³ bonds; and
a hydrogen-barrier material distributed in the core layer,
wherein the hydrogen-barrier material comprises a transition metal selected from one of Group IV or Group V of the periodic table.

19. The pellicle membrane according to claim 18, wherein the transition metal is selected from Period IV of the periodic table.

20. The pellicle membrane according to claim 19, wherein the hydrogen-barrier material further comprises oxygen and hydrogen.
